(19) United States
(12) Patent Application Publication
(10) Pub. No.: US 2020/0208802 A1
(43) Pub. Date: Jul. 2, 2020

(54) LAMP DEVICE

(71) Applicant: T.Y.C. BROTHER INDUSTRIAL CO., LTD., Tainan City (TW)

(72) Inventors: Min-Feng LIN, Tainan City (TW); Nan-Ming LIN, Kaohsiung City (TW)

(73) Assignee: T.Y.C. BROTHER INDUSTRIAL CO., LTD., Tainan City (TW)

(21) Appl. No.: 16/429,255

(22) Filed: Jun. 3, 2019

(30) Foreign Application Priority Data
Dec. 27, 2018 (TW) 107147469

(51) Int. Cl. F21V 5/04; H01L 33/50; H01L 33/60

(52) U.S. Cl. CPC F21V 5/04; H01L 33/60; H01L 33/50

(57) ABSTRACT

A lamp device includes a light emitting unit and a reflecting unit including first and second reflecting modules. The first reflecting module reflects light towards the second reflecting module and has a reflectivity substantially over 70% for light of wavelength ranging from 550 nm to 800 nm. The second reflecting module reflects light towards the first reflecting module and has a reflectivity that substantially ranges from 50% to 75% for light of wavelength ranging from 460 nm to 700 nm. The light emitting unit emits light toward the reflecting unit such that at least a part of the light emitted by the light emitting unit is reflected from one of the first reflecting module and the second reflecting module.

### CROSS-REFERENCE TO RELATED APPLICATION

This application claims priority of Taiwanese Invention Patent Application No. 107147469, filed on Dec. 27, 2018.

### FIELD

The disclosure relates to a lamp device, more particularly to a lamp device for a vehicle.

### BACKGROUND

Referring to FIGS. 1 and 2, a conventional lamp device used as a tail light installed at the rear of a car is illustrated. The conventional lamp device includes a lamp seat 11, a first support member 12, a reflecting module 13, a light emitting unit 14 mounted to the first support member 12, and a lamp shield 15 mounted rearwardly to the lamp seat 11 to shield the first support member 12, the reflecting module 13 and the light emitting unit 14. The first support member 12 and the reflecting module 13 are mounted to the lamp seat 11 and are disposed along a front-rear direction.

The first support member 12 is made of steel and has a polished reflecting surface 121. The reflecting surface 121 has a reflectivity of less than 60% for visible light. The reflecting module 13 includes a semi-reflecting film 131 and a second support member 132 that the semi-reflecting film 131 is formed on. The second support member 132 is made of a transparent material. The semi-reflecting film 131 has a reflectivity of approximately 40% to 80% for visible red light of wavelength ranging from 575 nm to 675 nm. The light emitting unit 14 includes a plurality of light emitting members 141 mounted in a ring shape on the first support member 12 and emitting visible red light.

The light pattern produced by the conventional lamp device is shown in FIG. 2. Other than the outermost ring of dotted red light indicated as R1 in FIG. 2, which is a real image produced directly from the light emitting members 141, the inner rings of dotted red light (indicated as R2 in FIG. 2) are virtual images produced through cooperation between the reflecting surface 121 and the semi-reflecting film 131. The real and virtual images cooperatively produce a three dimensional tunnel-like visual effect.

Even though the conventional lamp device can produce the three dimensional tunnel-like visual effect, the number of the inner rings of the virtual images is lacking, resulting a relative large dark region 16 in the center of the light pattern. Moreover, even though the semi-reflecting film 131 achieves semi-reflection with visible red light, it is unable to achieve the same for visible lights of other colors.

### SUMMARY

Therefore, the object of the disclosure is to provide a lamp device that can alleviate at least one of the drawbacks of the prior art.

According to the disclosure, a lamp device includes a reflecting unit and a light emitting unit.

The reflecting unit includes a first reflecting module and a second reflecting module. The first reflecting module is configured to reflect light towards the second reflecting module and has a reflectivity that is substantially over 70% for light of wavelength ranging from 550 nm to 800 nm. The second reflecting module is configured to reflect light towards the first reflecting module and has a reflectivity that substantially ranges from 50% to 75% for light of wavelength ranging from 460 nm to 700 nm.

The light emitting unit is connected to the reflecting unit and configured to emit light toward the reflecting unit in such a way that at least a part of the light emitted by the light emitting unit is reflected from one of the first reflecting module and the second reflecting module.

### BRIEF DESCRIPTION OF THE DRAWINGS

Other features and advantages of the disclosure will become apparent in the following detailed description of the embodiment and variations with reference to the accompanying drawings, of which:

FIG. 1 is an exploded perspective view of a conventional lamp device;

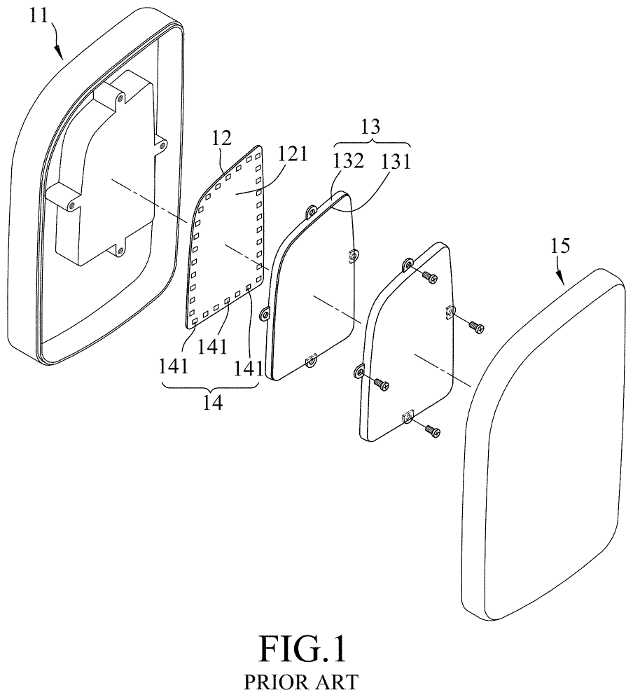

FIG. 2 is a photograph of a light pattern produced by the conventional lamp device;

FIG. 3 is an exploded perspective view of an embodiment of a lamp device according to the disclosure;

FIG. 4 is a sectional view of the embodiment;

FIG. 5 is a fragmentary sectional view, illustrating layers of a reflecting film of the embodiment;

FIG. 6 is a graph illustrating a reflectivity of an aluminum film of the embodiment for light of varying wavelength;

FIG. 7 is a graph illustrating a reflectivity of a reflecting film for light of different incident angles and varying wavelength;

FIG. 8 is a photograph illustrating a light pattern produced by the embodiment;

FIG. 9 is a fragmentary sectional view of a first variation of embodiment of the lamp device according to the disclosure;

FIG. 10 is a fragmentary sectional view of a second variation of the embodiment of the lamp device according to the disclosure;

FIG. 11 is a fragmentary sectional view of a third variation of the embodiment of the lamp device according to the disclosure;

FIG. 12 is a graph illustrating values of reflectivity of three combined film modules of respectively the first, second and third variations of the embodiment for varying wavelengths; and

FIG. 13 is a fragmentary sectional view of a fourth variation of the embodiment of the lamp device according to the disclosure.

### DETAILED DESCRIPTION

Before the present invention is described in greater detail, it should be noted that where considered appropriate, reference numerals or terminal portions of reference numerals have been repeated among the figures to indicate corresponding or analogous elements, which may optionally have similar characteristics.

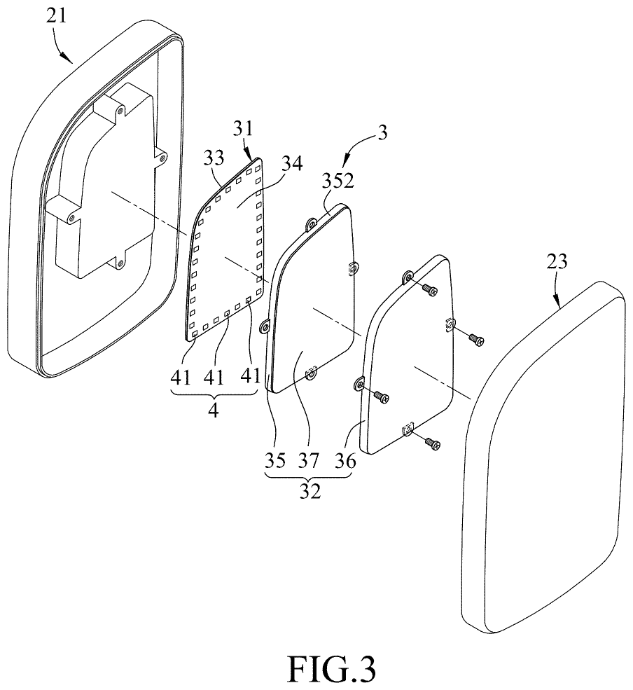

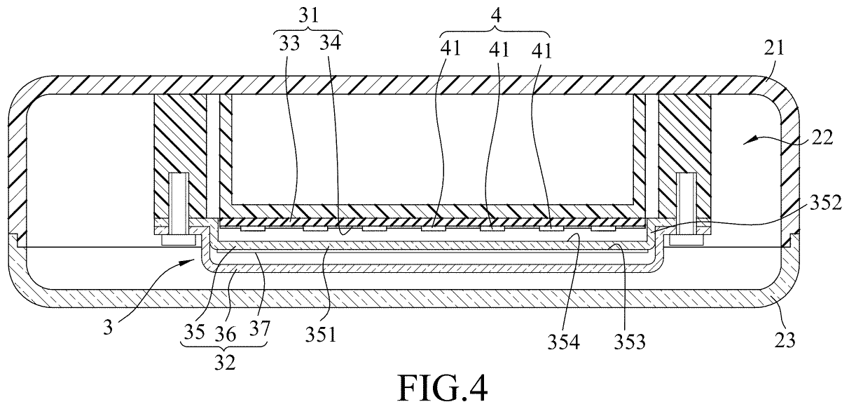

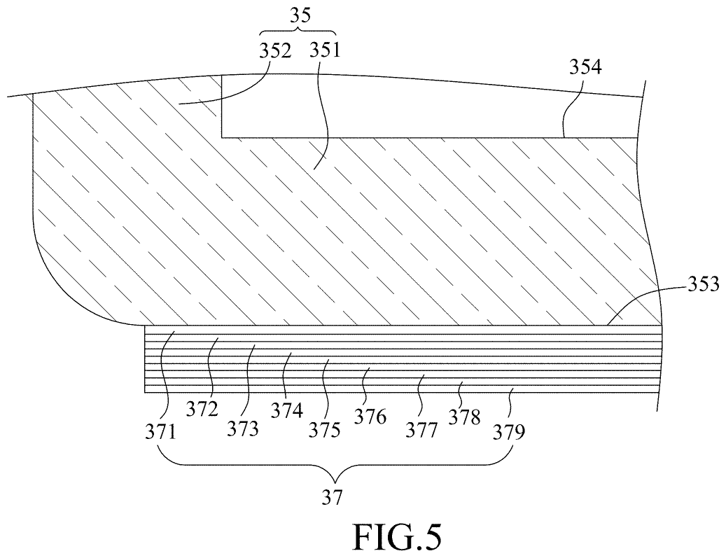

Referring to FIGS. 3 to 5, an embodiment of a lamp device according to the disclosure is exemplified as a vehicle lamp such as a taillight of automobiles or motorcycles.

The embodiment of the lamp device includes a lamp seat 21 adapted to be mounted to a vehicle, a lamp shield 23 mounted on the lamp seat 21 and cooperating with the lamp seat 21 to define a lamp space 22, a reflecting unit 3 mounted to the lamp seat 21 and received in the lamp space 22, and a light emitting unit 4 disposed on the reflecting unit 3. Light emitted from the light emitting unit 4 projects toward the lamp shield 2. The design and structure of the lamp seat 21 and the lamp shield 23 are well known to those skilled in the art and are omitted for the sake of brevity.

The reflecting unit 3 includes a first reflecting module 31 and a second reflecting module 32.

The first reflecting module 31 is configured to reflect light towards the second reflecting module 32 and has a reflectivity that is substantially over 70% for light of wavelength ranging from 550 nm to 800 nm. The first reflecting module 31 includes a first support member 33 and an aluminum film 34 deposited by evaporation on the first support member 33 and disposed between the first support member 33 and the second reflecting module 32. In this embodiment, the first support member 33 is substantially quadrilateral-shaped. The first support member 33 may be made of steel.

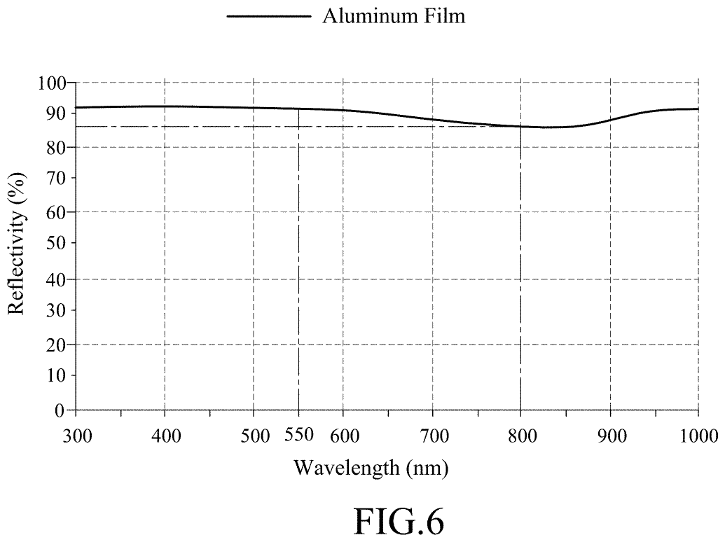

In this embodiment, the aluminum film 34 is formed on the first support member 33 through electron beam evaporation technique under pressure of 10⁻⁵ Torr and temperature of 60° C., using aluminum as a target and at an evaporation rate of 20 \acute{Å} per second. Referring further to FIG. 6, reflectivity of the aluminum film 34 for light of varying wavelength is shown. For light with an incident angle of 0° (i.e., normal incidence) and of wavelength ranging from 550 nm to 800 nm, the aluminum film 34 has an average reflectivity that is substantially over 85%. For visible red light of wavelength ranging from 575 nm to 675 nm, the average reflectivity is approximately 90.8%.

The second reflecting module 32 is connected to the first reflecting module 31, configured to reflect light towards the first reflecting module 31, and has a reflectivity that substantially ranges from 50% to 75% for light of wavelength ranging from 460 nm to 700 nm. The second reflecting module 32 includes a second support member 35 that is light-transmissible and coupled to the first reflecting module 31, a light-transmissible shielding member 36 coupled to the second support member 35 and being opposite to the first reflecting module 31, and a reflecting film 37 that is deposited by evaporation on the second support member 35, opposite to the first reflecting module 31, and disposed between the second support member 35 and the light-transmissible shielding member 36.

In this embodiment, the second support member 35 is made of a light-transmissible material such as acrylics, and includes a plate portion 351 that may be substantially quadrilateral-shaped, and a supporting portion 352 extending from a periphery of the plate portion 351 toward the lamp seat 21 to be mounted to the lamp seat 21. The plate portion 351 includes a first surface 353 for the reflecting film 37 to be deposited on, and a second surface 354 opposite to the first surface 353 and facing the first reflecting module 31. In certain embodiments, the second surface 354 may be concave to achieve desired optical effects, but may vary in actual practice depending on differing needs.

The shielding member 36 is similar in shape to the second support member 35 but larger in size such that it shields over the rear of and protects the second support member 35 and the reflecting film 37.

The reflecting film 37 has a reflectivity substantially between 50% and 75% for light of wavelength ranging from 460 nm to 700 nm, and includes a first deposited layer 371 formed on the second support member 35, and second, third, fourth, fifth, sixth, seventh, eighth and nine deposited layers 372, 373, 374, 375, 376, 377, 378, 379 stacked in order on the first deposited layer 371 in a direction away from the second support member 35.

The reflecting film 37 is formed layer-by-layer using the electron beam evaporation technique, under a pressure of 10⁻⁵ torr and a temperature of 80° C., using either silica or titanium oxide targets, and at the evaporation rate of 8 \acute{Å} per second.

In this embodiment, each of the first, third, fifth, seventh and ninth deposited layers 371, 373, 375, 377, 379 is exemplified to be made of titanium dioxide and has a refractive index of 2.28. Each of the second, fourth, sixth, and eighth deposited layers 272, 274, 276, 278 is exemplified to be made of silica and has a refractive index of 1.45.

In this embodiment, the first deposited layer 371 has a thickness of 28.6 nm, the second deposited layer 372 has a thickness of 19.5 nm, the third deposited layer 373 has a thickness of 64.1 nm, the fourth deposited layer 374 has a thickness of 165.0 nm, the fifth deposited layer 375 has a thickness of 102.6 nm, the sixth deposited layer 376 has a thickness of 94.4 nm, the seventh deposited layer 377 has a thickness of 60.8 nm, the eighth deposited layer 378 has a thickness of 96.7 nm, and the ninth deposited layer 379 has a thickness of 60.0 nm.

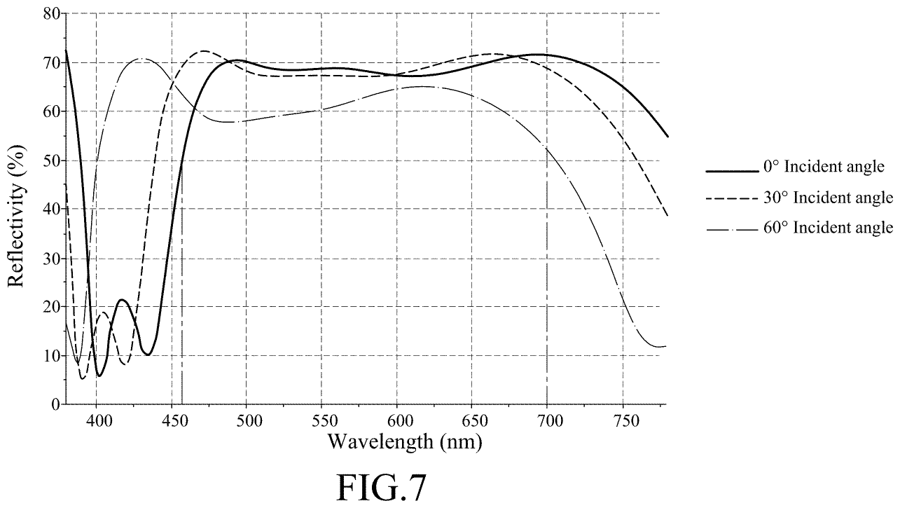

Referring to FIG. 7, the reflectivity of the reflecting film 37 for light of varying wavelength and at three different incident angles being 0°, 30°, and 60° was measured and plotted. During measurement, the reflecting film 37 is supported by a transparent substrate. From FIG. 7 it can be seen that the reflectivity of the reflecting film 37 for light of wavelength ranging from 460 nm to 700 nm is approximately 50% to 75%, providing desirable and relatively consistent semi-reflection.

In particular, for visible red light of wavelength ranging from 575 nm to 675 nm, when the angles of incidence are 0°, 30°, and 60°, the values of average reflectivity are respectively 68.2%, 69.1%, and 63.4%.

The light emitting unit 4 is connected to the reflecting unit 3 and configured to emit light toward the reflecting unit 3 in such a way that at least a part of the light emitted by the light emitting unit 4 is reflected from one of the first reflecting module 31 and the second reflecting module 32. In this embodiment, the light emitting unit 4 is connected to the first reflecting module 31 and emits the light toward the second reflecting module 32. The light emitting unit 4 includes a plurality of light emitting members 41 mounted to an outer ring portion of the first support member 33. In this embodiment, the light emitting members 41 are exemplified to be light emitting diodes that emit visible red light of wavelength ranging from 575 nm to 675 nm directed towards the first reflecting module 31.

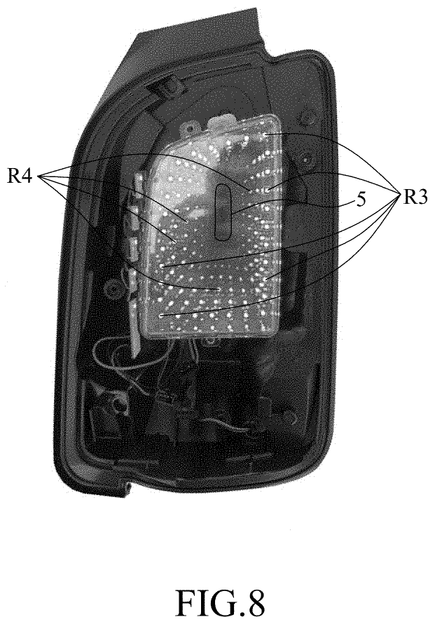

Referring to FIGS. 3, 4, and 8, a light pattern as shown in FIG. 8 can be produced by the embodiment. A portion of the light emitted by the light emitting members 41 transmits through the reflecting film 37 of the second reflecting module 32 to project into a user's eye, forming the outermost ring of dotted light (indicated as R3 in FIG. 8), and another portion of the light is reflected first by the reflecting film 37, then by the aluminum film 34 towards the reflecting film 37, where the another portion of the light partially transmits through the reflecting film 37 and is partially reflected by the reflecting film 37 again, and so on, forming multiple rings of dotted virtual image (indicated as R4 in FIG. 8) inside the outermost ring.

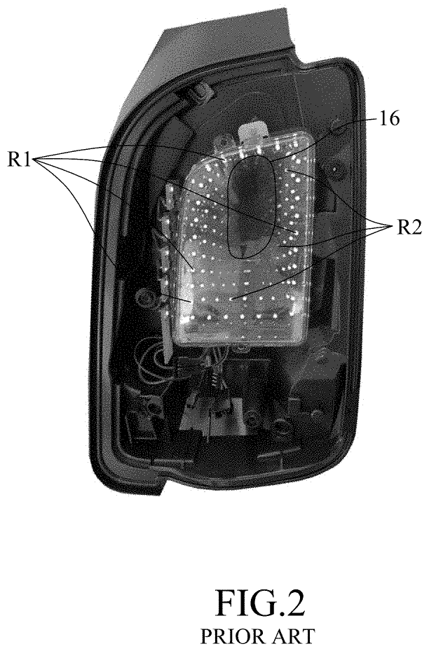

The aluminum film 34 of the embodiment has an average reflectivity of over 85% for light of wavelength ranging from 550 nm to 800 nm, which is higher than that of the conventional lamp device (less than 60%). The higher reflectivity allows the energy decay rate of the light to be reduced. Hence, in comparison to the light pattern of the conventional lamp device (see FIG. 2), the embodiment can produce more rings of dotted virtual image (see FIG. 8), reducing the area of a dark region 5 where no light can be seen. In other words, the embodiment produces better lighting than the conventional lamp device, having better warning effects and improving traffic safety.

Moreover, since the reflecting film 37 of the embodiment has reflectivity of 50% to 75% for light of wavelength ranging from 460 nm to 700 nm, even if the light emitting members 41 of this embodiment are changed to emit visible light of a different color from red, the light pattern of FIG. 8 may still be produced as the reflectivity of the reflective film 37 for light of wavelength ranging from 460 nm to 700 nm and is fairly consistent (see FIG. 7).

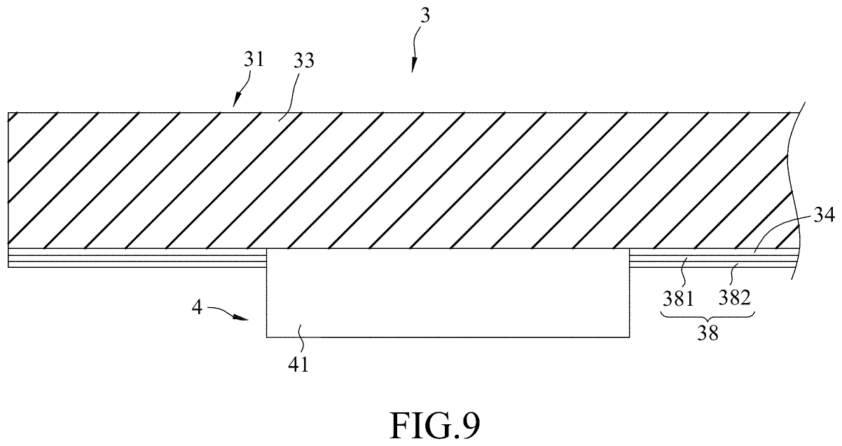

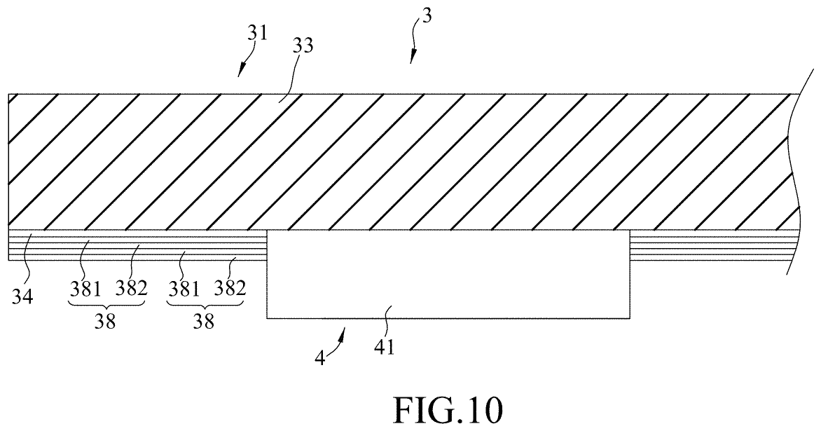

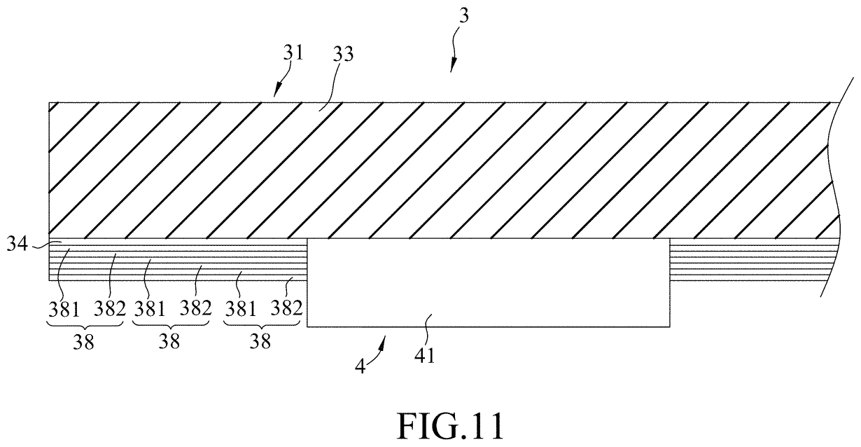

Referring to FIGS. 9 to 12, a first variation of the embodiment of the lamp device according to the disclosure has a structure similar to that of the embodiment, the difference being that, in the first variation, the first reflecting module 31 further includes at least one deposited film 38 formed on the aluminum film 34 and disposed between the aluminum film 34 and the second support member 32. The at least one deposited film 38 has a first film layer 381 that is connected to the aluminum film 34, and a second film layer 382 that is connected to the first film layer 381 and that is disposed between the first film layer 381 and the second reflecting module 32. The first film layer 381 has a refractive index of 1.45, a thickness of 107.2 nm, and is made of silica. The second film layer 382 has a refractive index of 2.28, a thickness of 68.4 nm, and is made of titanium dioxide. Second and third variations of the lamp device according to the disclosure are similar to the first variation, the differences being that the first reflecting module 31 of the second variation includes two of the aforementioned deposited films 38 and that the first reflecting module 31 of the third variation includes three of the aforementioned deposited films 38. In other embodiments, the first reflecting module 31 may include a plurality of the deposited films 38 stacked on the aluminum film 34 in a direction away from the first support member 33.

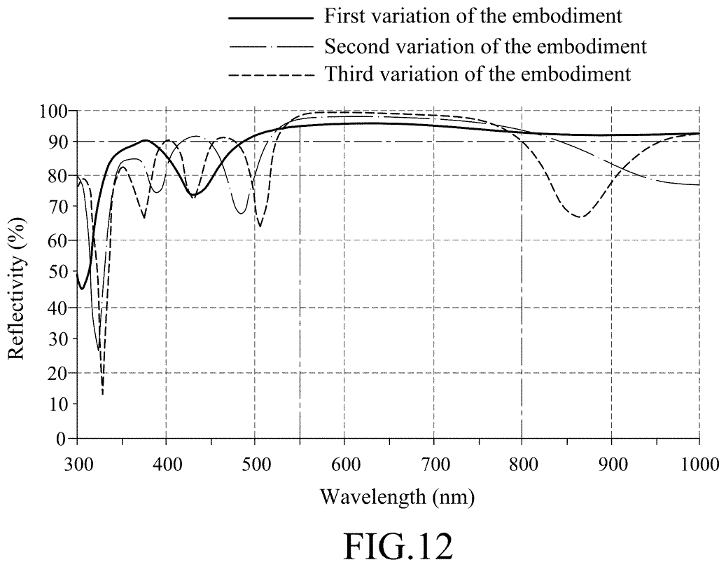

The values of reflectivity of three combined film modules each including the aluminum module 34 and the deposited film(s) 38 of the first, second and third variations of the embodiment, respectively, for light of varying wavelength are shown in FIG. 12. As can be seen, the average values of reflectivity of the combined film modules for light incident at 0° and of wavelength ranging from 550 nm to 800 nm are above 90%. More specifically, the values of reflectivity of the combined film modules of the first, second and third variations of the embodiment for visible red light of wavelength ranging from 575 nm to 675 nm are respectively 96%, 98.2% and even 99.2%. Thus, the lamp device of the first, second and third variations of the embodiment can produce more virtual images and better lighting effect.

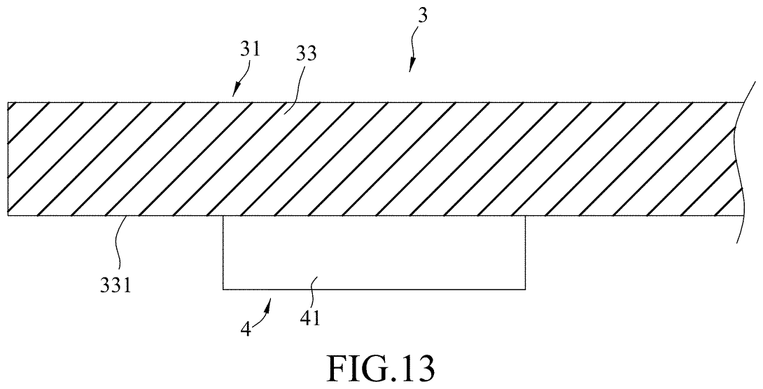

Referring to FIG. 13, a fourth variation of the embodiment of the lamp device according to the disclosure is similar to the embodiment, the differences being that the aluminum film 34 in the fourth variation is omitted, and that the first support member 33 of the first reflecting module 31 is made of aluminum. The first support member 33 has a polished reflecting surface 331 facing the second reflecting module 32 and has a reflectivity that is substantially over 70% for light of wavelength ranging from 550 nm to 800 nm. In this variation, the reflectivity for light of wavelength ranging from 550 nm to 800 nm is around 72%. The fourth variation shares the same benefits as the embodiment.

In sum, the lamp device of the disclosure has the following benefits:

1. The first reflecting module 31 can reduce the energy decay rate of light and cooperate with the second reflecting module 32 to increase the number of virtual images, thus reducing the size of the dark region 5.

2. The reflectivity/partial reflecting effect of both the first and second reflecting module 31, 32 are consistently desirable for light of wavelength ranging from 550 nm to 700 nm, thus the lamp device of this disclosure may be used with a variety of colors and in a wider variety of situations.

In the description above, for the purposes of explanation, numerous specific details have been set forth in order to provide a thorough understanding of the embodiment and variations. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiment and variations, it is understood that this disclosure is not limited to the disclosed embodiment and variations but is intended to cover various arrangements included within the spirit and scope of the broadest interpretation so as to encompass all such modifications and equivalent arrangements.

What is claimed is:

1. A lamp device comprising:
a reflecting unit including a first reflecting module and a second reflecting module, said first reflecting module being configured to reflect light towards said second reflecting module and having a reflectivity that is substantially over 70% for light of wavelength ranging from 550 nm to 800 nm, said second reflecting module being configured to reflect light towards said first reflecting module and having a reflectivity that substantially ranges from 50% to 75% for light of wavelength ranging from 460 nm to 700 nm; and
a light emitting unit connected to said reflecting unit and configured to emit light toward said reflecting unit in such a way that at least a part of the light emitted by said light emitting unit is reflected from one of said first reflecting module and said second reflecting module.

2. The lamp device as claimed in claim 1, wherein said second reflecting module includes a second support member that is light-transmissible and coupled to said first reflecting module, and a reflecting film that is deposited on said second support member and opposite to said first reflecting module, said reflecting film having a reflectivity substantially between 50% and 75% for light of wavelength ranging from 460 nm to 700 nm.

3. The lamp device as claimed in claim 2, wherein said reflecting film includes a first deposited layer formed on said second support member, and second, third, fourth, fifth, sixth, seventh, eighth and nine deposited layers stacked in order on said first deposited layer in a direction away from said second support member, each of said first, third, fifth, seventh and ninth deposited layers having a refractive index of 2.28, each of said second, fourth, sixth, and eighth deposited layers having a refractive index of 1.45.

4. The lamp device as claimed in claim 3, wherein said first deposited layer has a thickness of 28.6 nm, said second deposited layer having a thickness of 19.5 nm, said third deposited layer having a thickness of 64.1 nm, said fourth deposited layer having a thickness of 165.0 nm, said fifth deposited layer having a thickness of 102.6 nm, said sixth deposited layer having a thickness of 94.4 nm, said seventh deposited layer having a thickness of 60.8 nm, said eighth deposited layer having a thickness of 96.7 nm, said ninth deposited layer having a thickness of 60.0 nm.

5. The lamp device as claimed in claim 3, wherein each of said first, third, fifth, seventh and ninth deposited layers is made of titanium dioxide, and each of said second, fourth, sixth, and eighth deposited layers is made of silica.

6. The lamp device as claimed in claim 1, wherein said first reflecting module includes a first support member and an aluminum film deposited on said first support member and disposed between said first support member and said second reflecting module, said aluminum film having a reflectivity that is substantially over 85% for light of wavelength ranging from 550 nm to 800 nm.

7. The lamp device as claimed in claim 6, wherein said first reflecting module further includes at least one deposited film formed on said aluminum film and disposed between said aluminum film and said second support member, said at least one deposited film having a first film layer that is connected to said aluminum film, and a second film layer that is connected to said first film layer and that is disposed between said first film layer and said second reflecting module, said first film layer having a refractive index of 1.45, said second film layer having a refractive index of 2.28.

8. The lamp device as claimed in claim 7, wherein said first film layer has a thickness of 107.2 nm, and said second film layer has a thickness of 68.4 nm.

9. The lamp device as claimed in claim 7, wherein said first film layer is made of silica, and said second film layer is made of titanium dioxide.

10. The lamp device as claimed in claim 7, wherein said first reflecting module includes a plurality of said deposited films stacked on said aluminum film in a direction away from said first support member.

11. The lamp device as claimed in claim 6, wherein said first support member is made of steel.

12. The lamp device as claimed in claim 1, wherein said first reflecting module includes a first support member made of aluminum, said first support member having a polished reflecting surface facing said second reflecting module and a reflectivity that is substantially over 70% for light of wavelength ranging from 550 nm to 800 nm.

13. The lamp device as claimed in claim 1, wherein said second reflecting module is connected to said first reflecting module, said light emitting unit being connected to said first reflecting module and emitting the light toward said second reflecting module.
